(19) United States
(12) Patent Application Publication
(10) Pub. No.: US 2020/0249281 A1
(43) Pub. Date: Aug. 6, 2020

(54) INFORMATION PROCESSING APPARATUS AND COMPUTER-READABLE RECORDING MEDIUM STORING BATTERY DETERIORATION DIAGNOSIS PROGRAM

(71) Applicant: FUJITSU LIMITED, Kawasaki-shi (JP)

(72) Inventors: Masatoshi Ishii, Kawasaki (JP); YOSHIYASU NAKASHIMA, Kawasaki (JP)

(73) Assignee: FUJITSU LIMITED, Kawasaki-shi (JP)

(21) Appl. No.: 16/711,504

(22) Filed: Dec. 12, 2019

(30) Foreign Application Priority Data
Feb. 4, 2019 (JP) 2019-018229

(51) Int. Cl. G01R 31/392; G01R 31/367; G01R 31/389

(52) U.S. Cl. CPC G01R 31/392; G01R 31/389; G01R 31/367

(57) ABSTRACT

An information processing apparatus includes: a memory; and a processor coupled to the memory and configured to: obtain an actual measurement voltage at a time of a voltage change of a battery; estimate an internal impedance of the battery based on an equivalent circuit model of the battery in which a Warburg impedance is represented by an approximate equation using an equivalent circuit which is a series circuit of CR circuits and has steps of a power of 10 as a time constant of the CR circuit and the actual measurement voltage; determine a deterioration state of the battery based on the internal impedance; and notify of deterioration of the battery in a case where the deterioration diagnosis unit detects deterioration.

### CROSS-REFERENCE TO RELATED APPLICATION

This application is based upon and claims the benefit of priority of the prior Japanese Patent Application No. 2019-18229, filed on Feb. 4, 2019, the entire contents of which are incorporated herein by reference.

### FIELD

The embodiment discussed herein is related to a battery deterioration diagnosis apparatus, a battery deterioration analysis circuit, and a computer-readable recording medium storing a battery deterioration diagnosis program,

### BACKGROUND

In order to realize a low carbon society or efficiently use energy, an increase in utilization of energy devices such as photovoltaic power generation (PV), storage batteries is expected. When a large amount of energy supply devices such as photovoltaic power generation are introduced into a power system, there is a concern that a large influence is exerted on reception operation of a power company due to the output fluctuation. In order to perform a stable system operation, it is desired to consider countermeasures such as reducing a rate of change in demand by using equipment such as a heat pump type water heater, a storage battery.

Examples of the related art include Japanese Laid-open Patent Publication No. 2011-141228, Japanese Laid-open Patent. Publication No. 2015-206758, Japanese Laid-open Patent Publication No. 2005-274280, and Japanese. Laid-open Patent. Publication No. 2017-16991.

### SUMMARY

According to an aspect of the embodiments, an information processing apparatus includes: a memory; and a processor coupled to the memory and configured to: obtain an actual measurement voltage at a time of a voltage change of a battery; estimate an internal impedance of the battery based on an equivalent circuit model of the battery in which a Warburg impedance is represented by an approximate equation using an equivalent circuit which is a series circuit of CR circuits and has steps of a power of 10 as a time constant of the CR circuit and the actual measurement voltage; determine a deterioration state of the battery based on the internal impedance; and notify of deterioration of the battery in a case where the deterioration diagnosis unit detects deterioration.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a battery deterioration diagnosis system according to an embodiment;

FIG. 2 is a diagram illustrating an equivalent circuit model of a battery;

FIG. 3 is a diagram illustrating an equivalent circuit of a Warburg impedance;

FIG. 4 is a diagram illustrating an example of a parameter value in a case where the Warburg impedance is represented by the equivalent circuit;

FIG. 5 is a diagram for explaining an overlap of first order LPF characteristics;

FIG. 6 is a diagram illustrating a comparison between an estimated waveform using an approximate solution and a waveform based on an actual measurement value;

FIG. 7 is a block diagram of a deterioration diagnosis server;

FIG. 8 is a flowchart of an estimation process of an equivalent circuit parameter;

FIG. 9 is a flowchart of a deterioration diagnosis process;

FIG. 10 is a diagram illustrating an example of an analysis result of an internal impedance;

FIG. 11 is a diagram illustrating an estimated value of an equivalent circuit parameter in a case where a battery of 4.5 Ah is used;

FIG. 12 is a diagram illustrating an actual measurement value in a case where a battery of 4.5 Ah is used;

FIG. 13 is a diagram illustrating an estimated value of an equivalent circuit parameter in a case where a battery of 8.0 Ah is used;

FIG. 14 is a diagram illustrating an actual measurement value in a case where the battery of 8.0 Ah is used; and

FIG. 15 is a hardware configuration diagram of the deterioration diagnosis server.

### DESCRIPTION OF EMBODIMENTS

As one method of adjusting the demand using such various devices, a use of a demand response (DR) may be considered. The demand response is a technology of adjusting a demand by providing an economic merit. For example, as utilization of the demand response, there is a demand adjustment for controlling a storage battery of a consumer by giving an incentive or a penalty to charge and discharge of the storage battery of the consumer. In order to more efficiently utilize the demand response, it is desirable to use solar power generation, wind power generation, an energy management system using a co-generator and a storage battery.

In order to significantly deal with the demand response, it is important to accurately grasp a state of a storage battery system. In order to accurately grasp the state of the storage battery system, an appropriate deterioration diagnosis of the storage battery system is required. One method of diagnosing deterioration in the storage battery system is, for example, a method in which charge and discharge are actually performed to measure a discharge capacity. Meanwhile, in the method of actually performing charge and discharge, measurement for a long time is performed, and rapid diagnosis is difficult, and this also may be a factor or deteriorating the storage battery.

Another method of diagnosing deterioration in the storage battery system is to evaluate deterioration of the storage battery system by using a change in a direct current (DC) resistance. Meanwhile, since the DC resistance is a resistance of approximate milliohm, a measurement error is large, so a deterioration diagnosis performance is poor and it is difficult to use the DC resistance in an actual operation.

There is also a deterioration diagnosis using an internal equivalent model of a storage battery. For example, in the internal equivalent circuit model of the storage battery, a parallel circuit of a resistor and a capacitor is disposed together with a DC resistor. In a case where the storage battery is deteriorated, a change in a resistance in the parallel circuit is larger than a change in a resistance of the DC resistor. Therefore, by detecting the change in the resistance in the parallel circuit in the internal equivalent circuit model of the storage battery, it is possible to perform deterioration diagnosis with high accuracy.

In order to measure a resistance value of the resistor in the parallel circuit in the internal equivalent circuit model of the storage battery, an AC method using a frequency domain or an analysis using a transient response using a time domain is used. In an accurate deterioration diagnosis for the storage battery system, impedance measurement using a current at the time of an actual operation is required.

In the measurement of internal impedance by the AC method, a method of measuring the internal impedance from a frequency change of a minute alternating current (AC) signal is used. Meanwhile, since a DC resistance in the internal equivalent circuit model of the storage battery or a resistance in the parallel circuit has a current dependency, it is difficult to obtain the resistance value in the actual operation. Therefore, in a case of more accurately performing deterioration diagnosis on the storage battery system, it is appropriate to use analysis by a transient response characteristic.

The internal impedance of the storage battery includes a Warburg impedance component of ion conduction. Although the Warburg impedance component may be easily calculated when a current change is an ideal step change such as a Heaviside step function, it is difficult to calculate the impedance component since waveform distortion is usually generated. In the storage battery system, since an ion conductive component is coupled to a capacitance, it takes a long time to calculate the impedance. In a case of calculating the impedance, since the calculation requires much time and power when solving a combinational optimization problem, it is required to perform the analysis with a small amount of calculation.

Therefore, an approximation method using an equivalent model using a foster type circuit is considered to be used to obtain the impedance component of the Warburg impedance component. In a case of the approximation method using the equivalent model using the foster type circuit, a frequency range used for diffraction is as follows, For analyzing a capacitor resistance (CR) time constant of several 10 of msec, 1 kHz is used as a sampling frequency. According to a sampling theorem, a frequency of 1 kHz does not include information equal to or more than 500 Hz. It takes 1 second to analyze the internal impedance of the storage battery. In a frequency range of the analysis for 1 second, the analysis is performed up to a frequency of 0.5 Hz. For example, since analysis for a frequency of 500 Hz is performed each 0.5 Hz, in a case of the approximation method using the equivalent model using the foster type circuit, a frequency response range of at least 3 digits is analyzed.

As a technology of evaluating a battery characteristic in consideration of a Warburg impedance, a current waveform is divided into minute step functions, and transient response waveforms are calculated by synthesis of the step functions. For example, an AC signal is applied to a secondary battery to estimate a Warburg impedance, and a circuit parameter is estimated from a transient response waveform of a current voltage. As another technology of diagnosing deterioration, a deviation between a terminal voltage measured for each minute unit corresponding to a discharge current and a calculated voltage is calsulated, and a constant of an element of an equivalent circuit is obtained so that a deviation square sum or a deviation average becomes small so as to determine a state of the battery. For example, data at a transient response is extracted from current measurement data of a secondary battery, and a circuit parameter of an electric equivalent circuit at completion of discharge of the secondary battery is obtained, and deterioration diagnosis is performed.

Meanwhile, in an equivalent model using a normal foster type circuit, a time constant of each CR circuit is set to (2n−1)². Therefore, in order to obtain a frequency response range of 3 digits, 16 CR circuits are used, and it is difficult to suppress the amount of calculation.

When a transient response waveform is calculated by a step function synthesis method, since elements from the beginning are stacked, highly accurate calculation easily affected by an error is required. It is required to perform the calculation until completion of analysis on all divided steps, and in a case where the number of divisions is increased to improve calculation accuracy, the amount of calculation is increased. Since a calculation time or an error varies depending on the number of divisions, the number of divisions is optimized for each waveform to be analyzed, so the amount of calculation is increased.

It is difficult to apply the technology in which an AC signal is applied to a secondary battery to estimate a Warburg impedance, to a storage battery which outputs DC electricity. A constant of an element of an equivalent circuit is obtained from deviation between a terminal voltage and a calculated voltage for each minute unit or data at the time of a transient response is extracted from measurement data to obtain a circuit parameter, a Warburg impedance is not considered, and it is difficult to perform deterioration diagnosis with accuracy.

A battery deterioration diagnosis apparatus, a battery deterioration analysis circuit, and a computer-readable recording medium storing a battery deterioration diagnosis program capable of accurately performing life diagnosis on a storage battery with a small amount of calculation may be provided.

Hereinafter, an embodiment of a battery deterioration diagnosis apparatus, a battery deterioration analysis circuit, and a computer-readable recording medium storing a battery deterioration diagnosis program disclosed in the present application will be described in detail with reference to the drawings. The battery deterioration diagnosis apparatus, the battery deterioration analysis circuit, and the computer-readable recording medium storing the battery deterioration diagnosis program disclosed in the present application are not limited to the embodiment to be described below.

### EMBODIMENT

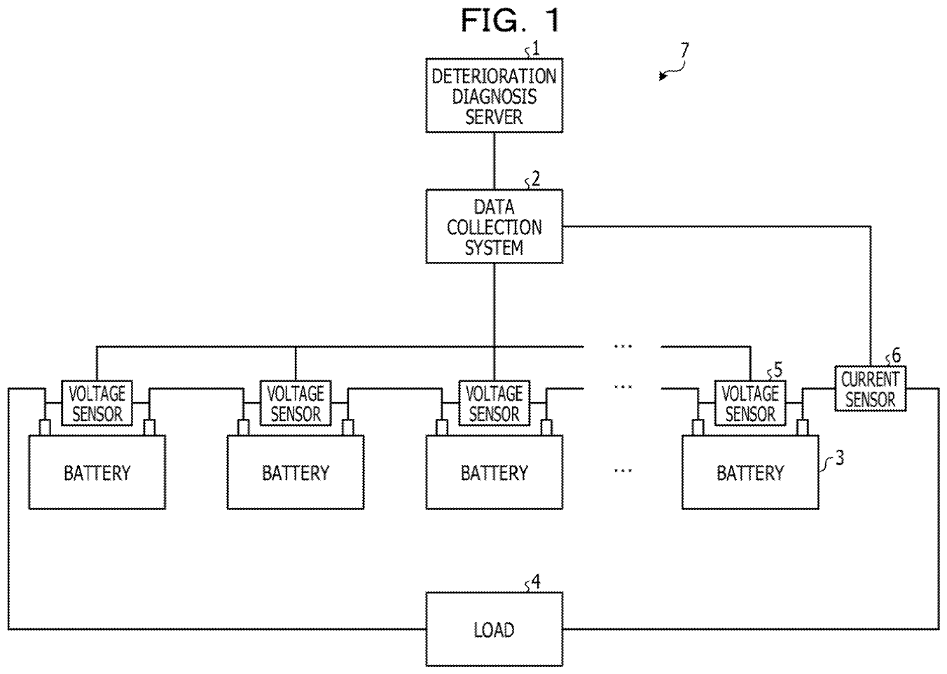

FIG. 1 is a diagram illustrating a battery deterioration diagnosis system according to the embodiment. An electronic deterioration diagnosis system 7 includes a deterioration diagnosis server 1, a data collection system 2, a battery 3, a load 4, a voltage sensor 5, and a current sensor 6.

One or a plurality of batteries 3 are coupled in series. The battery 3 is, for example, a lead-acid battery. The battery 3 is mounted on, for example, an uninterruptible power supply (UPS).

The load 4 is coupled to the battery 3. The load 4 is driven by receiving power supplied from the battery 3. The load 4 is, for example, an information processing device.

The voltage sensor 5 is disposed in the same number as the battery 3, and is coupled in parallel with the battery 3. When each voltage sensor 5 receives a load change signal indicating occurrence of a load change in the load 4, the voltage sensor 5 starts measurement of a voltage value of the corresponding battery 3, and transmits the measurement result to the data collection system 2. The load change signal is a signal input from a manager to the voltage sensor 5 and the current sensor 6.

The current sensor 6 is coupled in series with the battery 3. When a load change signal is received, the current sensor 6 measures a current value flowing through a load 4 supplied from one or a series of batteries 3 coupled in series.

The data collection system 2 is, for example, a communication device such as a router. The data collection system 2 collects voltage measurement data which is a voltage value of each battery 3 measured by each voltage sensor 5, and current measurement data which is a current value flowing through the load 4 measured by the current sensor 6. The data collection system 2 outputs the collected voltage measurement data and current measurement data to the deterioration diagnosis server 1.

The deterioration diagnosis server 1 is a device for diagnosing deterioration of the battery 3. The deterioration diagnosis server 1 receives an input of the voltage measurement data and current measurement data from the data collection system 2. The deterioration diagnosis server 1 determines a deterioration state of the battery 3 by using the voltage measurement data and the current measurement data. In a case where the deterioration of the battery 3 is detected, the deterioration diagnosis server 1 notifies the manager of the deterioration of the battery 3 by displaying a warning message or the like.

Hereinafter, determination of the deterioration state by the deterioration diagnosis server 1 will be described below. The deterioration diagnosis server 1 has a parameter value in advance included in an equivalent circuit model to be described below in a case where the battery 3 is represented by using the equivalent circuit model. Hereinafter, the parameter included in the equivalent circuit model representing the battery 3 is referred to as an “equivalent circuit parameter”.

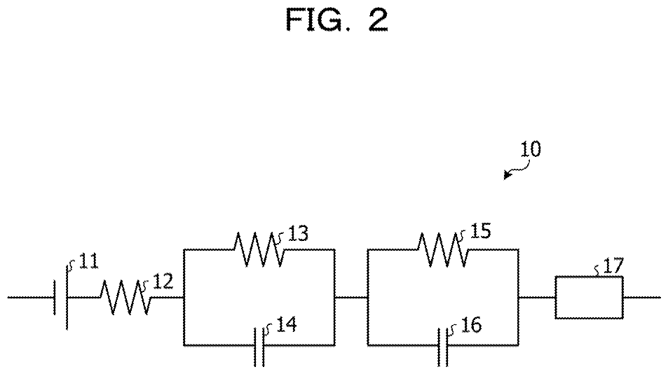

FIG. 2 is a diagram illustrating an equivalent circuit model of a battery. In the present embodiment, the equivalent circuit model 10 illustrated in FIG. 2 is used as an equivalent circuit model of the battery 3. The equivalent circuit model 10 is an equivalent circuit in which the Warburg impedance is coupled to a CR circuit in series, and is a model in which the CR circuit is added to an equivalent circuit model called a Modified Randles model.

In the equivalent circuit model 10, a DC power supply 11 and a resistor 12 are coupled in series. A CR circuit in which a resistor 13 and a capacitor 14 are coupled in parallel, and a CR circuit in which a resistor 15 and a capacitor 16 are coupled in parallel are coupled to the resistor 12 in series. A Warburg impedance 17 is coupled in series to the CR circuit including the resistor 15 and the capacitor 16.

An output voltage of the DC power supply 11 is an open circuit voltage (OCV). A resistance value of the resistor 12 is R0. A resistance value of the resistor 13 is R. A capacitance of the capacitor 14 is C1. A resistance value of the resistor 15 is R2. A capacitance of the capacitor 16 is C2. An impedance of the Warburg impedance 17 is Zw. R0 to R3, C1 and C2, and Dw are equivalent circuit parameters.

At this time, in a case where the battery 3 is represented by the equivalent circuit model 10, an internal impedance of the battery 3 is represented by the following equation (1) when Laplace transform is performed.

$$ZO ( s ) = RO + \frac{R 1}{1 + sC 1 R 1} + \frac{R 2}{1 + sC 2 R 2} + \frac{Dw}{\sqrt{s}} \qquad ( 1 )$$

First to third terms on the left side of the equation 1 correspond to an impedance of a circuit including the resistor 12, the resistor 13, the capacitor 14, the resistor 15, and the capacitor 16. For example, the second term corresponds to an impedance of the CR circuit including the resistor 13 and the capacitor 14. The third term corresponds to an impedance of the CR circuit including the resistor 15 and the capacitor 16.

A fourth term on the left side of the equation 1 corresponds to Zw which is an impedance of the Warburg impedance 17. s is a value obtained by performing Laplace transform on jω with respect to an angular frequency ω. Dw is a Warburg coefficient.

In order to analyze a predetermined current-voltage waveform instead of an ideal step current waveform, it is appropriate to use analysis by Z-transform. Meanwhile, it is difficult to perform Z-transform on the fourth term on the left side corresponding to the Warburg impedance 17 in the equation (1). Therefore, the following approximate equation is introduced.

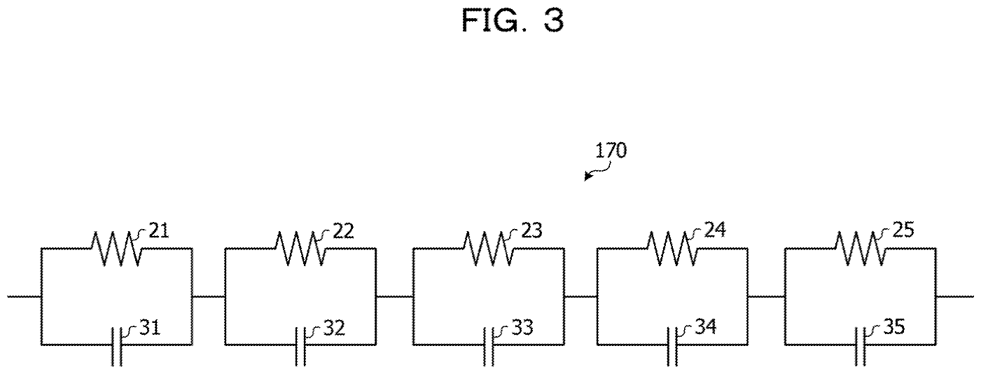

FIG. 3 is a diagram illustrating an equivalent circuit of a Warburg impedance. An equivalent circuit 170 is an equivalent circuit model of the Warburg impedance 17 using a fifth-order foster type series circuit,

The equivalent circuit 170 includes a CR circuit in which a resistor 21 and a capacitor 31 are coupled in parallel, a CR circuit in which a resistor 22 and a capacitor 32 are coupled in parallel, and a CR circuit in which a resistor 23 and a capacitor 33 are coupled in parallel. The equivalent circuit 170 includes a CR circuit in which a resistor 24 and a capacitor 34 are coupled in parallel, and a CR circuit in which a resistor 25 and a capacitor 35 are coupled in parallel. In the equivalent circuit 170, the respective CR circuits described above are coupled in series. A time constant of each CR circuit is steps of a power of 10.

A resistance value of the resistor 21 is Rw1. A resistance value of the resistor 22 is Rw2. A resistance value of the resistor 23 is Rw3. A resistance value of the resistor 24 is Rw4, A resistance value of the resistor 25 is Rw5.

A capacitance of the capacitor 31 is Cw1. A capacitance of the capacitor 32 is Cw2.A capacitance of the capacitor 33 is Cw3. A capacitance of the capacitor 34 is Cw4. A capacitance of the capacitor 35 is Cw5.

In a case where the Warburg impedance 17 is represented by the equivalent circuit 170, Zw which is an impedance may be approximated as represented by the following equation (2).

$$Zw ( s ) = \frac{Dw}{\sqrt{s}} \approx Dw {\sum }_{i = 1}^{5} \frac{Rwi}{1 + sCwiRwi} \qquad ( 2 )$$

Rw1 to Rw5 and Cw1 to Cw5 obtained by minimizing an error function represented by the following equation (3) are values of respective parameters in a case where the Warburg impedance 17 is represented by the equivalent circuit 170. E represents an error function. In this calculation, s is jω which is a value of z in a case of using an ideal step function to verify a frequency response.

$$E = {\{ Re [ \frac{1}{\sqrt{s}} - {\sum }_{i = 1}^{5} \frac{Rwi}{1 + sCwiRwi} ] \}}^{2} + {\{ Im [ \frac{1}{\sqrt{s}} - {\sum }_{i = 1}^{5} \frac{Rwi}{1 + sCwiRwi} ] \}}^{2} \qquad ( 3 )$$

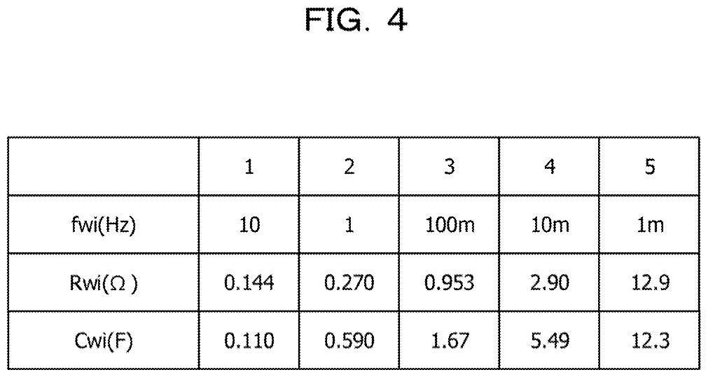

FIG. 4 is a diagram illustrating an example of a parameter value in a case where a Warburg impedance is represented by an equivalent circuit. The number of the uppermost stage in FIG. 4 indicates a number of stages of the CR circuit in the equivalent circuit 170, and corresponds to a number obtained in a case where the number is counted from left to right in the CR circuit. Rw1, which is a resistance value of the resistor 21 in the CR circuit in the first stage, is 0.144 Ω, and Cw1, which is a capacitance of the capacitor 31, is 0.110 F. Rw2,which is a resistance value of the resistor 22 in the CR circuit in the second stage, is 0.270 Ω, and Cw2, which is a capacitance of the capacitor 32, is 0.590 F. Rw3, which is a resistance value of the resistor 23 in the CR circuit in the third stage, is 0.953 Ω, and Cw3, which is a capacitance of the capacitor 33, is 1.67 F. Rw4, which is a resistance value of the resistor 24 in the CR circuit in the fourth stage, is 2.90 Ω, and Cw4, which is a capacitance of the capacitor 34, is 5.49 F. Rw5, which is a resistance value of the resistor 25 in the CR circuit in the fifth stage, is 12.9 Ω, and Cw5, which is a capacitance of the capacitor 35, is 12.3 F.

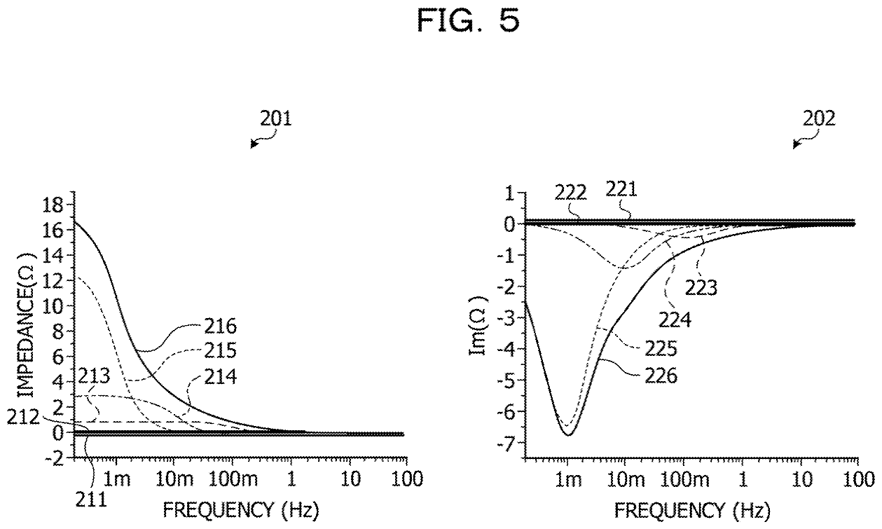

Accuracy of Rw1 to Rw5 and Cw1 to Cw5 representing the obtained Warburg impedance 17 will be verified. An approximate solution of the error function is obtained by overlapping first-order low pass filter (LPF) characteristics. FIG. 5 is a diagram for explaining an overlap of the first-order LPF characteristics. A graph 201 in FIG. 5 is a graph representing a real number component. A graph 202 is a graph representing an imaginary component.

Lines 211 to 215 in the graph 201 represent real number components of LPF characteristics in a case using of Rw1 to Rw5 and Cw1 to Cw5 obtained by using the equation (3). The line 211 represents a LPF characteristic of the CR circuit including the resistor 21 and the capacitor 31 having a resonant frequency of 10 Hz. The line 212 represents a LPF characteristic of the CR circuit including the resistor 22 and the capacitor 32 having a resonant frequency of 1 Hz. The line 213 represents a LPF characteristic of the CR circuit including the resistor 23 and the capacitor 33 having a resonance frequency of 100 MHz. The line 214 represents a LPF characteristic of the CR circuit including the resistor 24 and the capacitor 34 having a resonant frequency of 10 MHz. The line 215 represents a LPF characteristic of the CR circuit including the resistor 25 and the capacitor 5 having a resonant frequency of 1 MHz. When the lines 211 to 215 are overlapped with one another, a line 216 is obtained. This line 216 becomes an approximate solution of real number components in a case where the Warburg impedance 17 is represented by the equivalent circuit 170.

Lines 221 to 225 in the graph 202 represent imaginary components of LPF characteristics in a case of using Rw1 to Rw5 and Cw1 to Cw5 obtained by using the equation (3). The line 221 represents a LPF characteristic of the CR circuit including the resistor 21 and the capacitor having a resonant frequency of 10 Hz. The line 222 represents a LPF characteristic of the CR circuit including the resistor 22 and the capacitor 2 having a resonant frequency of 1 Hz. The line 223 represents a LPF characteristic of the CR circuit including the resistor 23 and the capacitor 33 having a resonance frequency of 100 MHz. The line 224 represents a LPF characteristic of a CR circuit including the resistor 24 and the capacitor 34 having a resonant frequency of 10 MHz. The line 225 represents a LPF characteristic of a CR circuit including the resistor 25 and the capacitor 35 having a resonant frequency of 1 MHz. When the lines 221 to 225 are overlapped with one another, a line 226 is obtained. This line 226 becomes an approximate solution of imaginary components in a case where the Warburg impedance 17 is represented by the equivalent circuit 170.

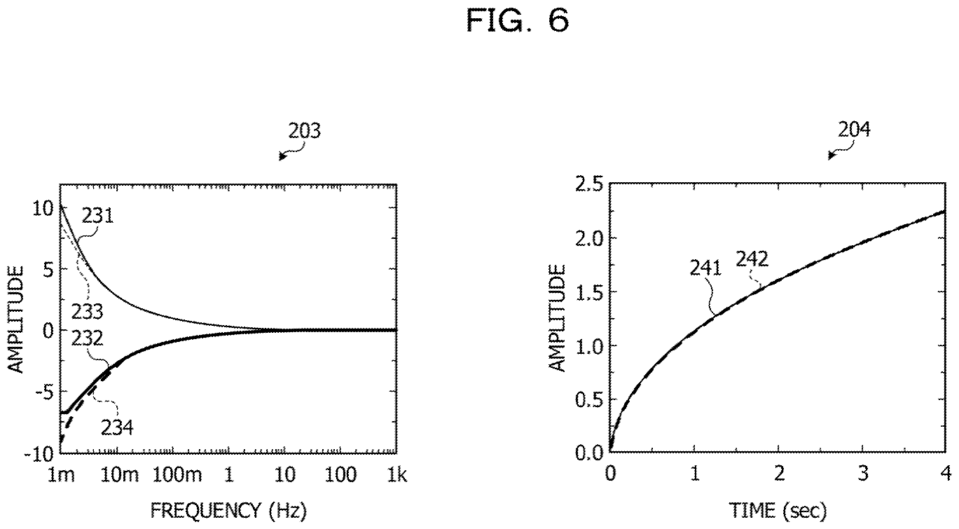

The approximate solution of the imaginary component and the real number component in the case where the Warburg impedance 17 is represented by the equivalent circuit 170 is compared with an actual measurement value of a response characteristic of the Warburg impedance 17. FIG. 6 is a diagram illustrating a comparison between an estimated waveform using an approximate solution and a waveform based on an actual measurement value.

A graph 203 in FIG. 6 is a graph illustrating a comparison between an estimated waveform of a frequency response characteristic and a waveform of an actual measurement. A line 231 represents a real number component of an estimated waveform using an approximate solution calculated based on the equivalent circuit 170. A line 232 represents an imaginary component of the estimated waveform using the approximate solution calculated based on the equivalent circuit 170. A line 233 represents a real number component of a waveform obtained from an actual measurement value of a frequency response characteristic of the Warburg impedance 17. A line 234 represents an imaginary component of another waveform obtained from the actual measurement value of the frequency response characteristic of the Warburg impedance 17.

In the graph 203, 500 Hz to 0.5 Hz is a frequency range of 3 digits. As illustrated in the graph 203, the approximate solution of the real number component in the case where the Warburg impedance 17 is represented by the equivalent circuit 170 is approximated to the actual measurement value of the frequency response characteristic of the Warburg impedance 17 in the frequency range of 500 Hz to 0.5 Hz. For example, the equivalent circuit 170 may accurately represent the Warburg impedance 17 in the frequency range of 3 digits.

A graph 204 is a graph illustrating a comparison between an estimated waveform of a transient response characteristic and a waveform of a real measurement. A line 241 represents an approximate solution of a transient response characteristic in a case of using the equivalent circuit 170. A line 242 represents an actual measurement value. In this manner, for the transient response characteristic, it may also be said that the approximate solution is approximate to the actual measurement value. Also in this point, the equivalent circuit 170 accurately represents the Warburg impedance 17.

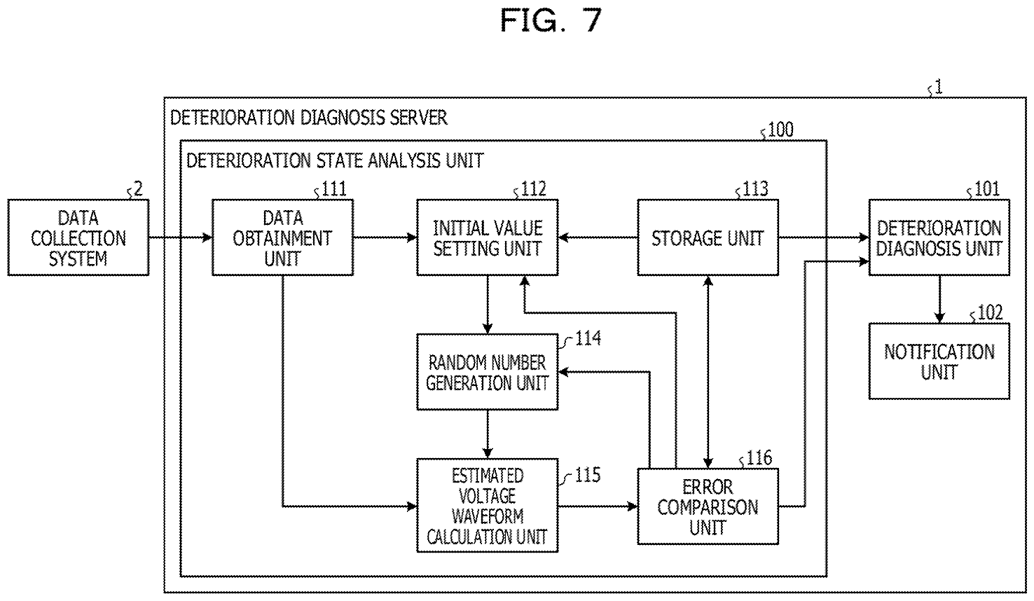

FIG. 7 is a block diagram of a deterioration diagnosis server. As illustrated in FIG. 7, the deterioration diagnosis server 1 includes a deterioration state analysis unit 100, a deterioration diagnosis unit 101, and a notification unit 102. The deterioration state analysis unit 100 includes a data obtainment unit 111, an initial value setting unit 112, a storage unit 113, a random number generation unit 114, an estimated voltage waveform calculation unit 115, and an error comparison unit 116. The deterioration diagnosis server 1 is an example of a “battery deterioration diagnosis apparatus”, and the deterioration state analysis unit 100 is an example of a “battery deterioration analysis circuit”.

The storage unit 113 holds values of Rw1 to Rw5 and Cw1 to Cw5 in the case where the Warburg impedance 17 is represented by using the equivalent circuit 170.

The data obtainment unit 111 receives inputs of a voltage value and a current value of each battery 3 from the data collection system 2. The data obtainment unit 111 outputs the obtained voltage value and current value of each battery 3 to the estimated voltage waveform calculation unit 115. The data obtainment unit 111 notifies the initial value setting unit 112 of a start of a deterioration state determination process. The data obtainment unit 111 corresponds to an example of an “obtainment unit”.

The initial value setting unit 112 receives the notification of the start of the deterioration state determination process from the data obtainment unit 111. The initial value setting unit 112 sets R0 to R3, which are resistance values of the resistors 12, 13, and 15, and sets initial values of C1 and C2, which are capacitances of the capacitors 14 and 16, in a case where the battery 3 is represented by the equivalent circuit model 10. The initial value setting unit 112 sets an initial value of Dw, which is a Warburg coefficient of the Warburg impedance 17.

The deterioration state analysis unit 100 estimates an equivalent circuit parameter of the equivalent circuit model 10 for the battery 3, and performs optimization by repeating the estimation process using a Monte Carlo method. In the first estimation process, the initial value setting unit 112 sets an appropriate value to an initial value of the equivalent circuit parameter. On the other hand, after the second estimation process, the initial value setting unit 112 obtains values of equivalent circuit parameters stored in the storage unit 113, and sets the values to initial values of R0 to R3, C1 and C2, and Dw.

Thereafter, the initial value setting unit 112 outputs the initial value of the equivalent circuit parameter to the random number generation unit 114. When an execution request of the estimation process is received from the error comparison unit 116, the initial value setting unit 112 executes the setting and the output of the initial value of the equivalent circuit parameter again.

The random number generation unit 114 receives the input of the initial value of the equivalent circuit parameter from the initial value setting unit 112. The random number generation unit 114 generates a random number for each equivalent circuit parameter by using the obtained initial value.

The random number generation unit 114 gradually reduces generation deviation of a random number every time the estimation process is repeated, and converges a value of the equivalent circuit parameter. For example, in the first estimation process, the random number generation unit 114 generates a random number with a random number generation deviation of 10%. Thereafter, the random number generation unit 114 reduces the random number generation deviation to 5%, 1%, and 0.5% for each repetition of the estimation process. The random number generation unit 114 outputs the generated random number for each equivalent circuit parameter to the estimated voltage waveform calculation unit 115 as a value of each equivalent circuit parameter.

Thereafter, when receiving a re-execution request for the random number generation process from the error comparison unit 116, the random number generation unit 114 executes again the random number generation for each equivalent circuit parameter by using the initial value. The random number generation unit 114 repeats the process of outputting the generated random number to the estimated voltage waveform calculation unit 115 as a value of each equivalent circuit parameter.

The estimated voltage waveform calculation unit 115 receives an input of measurement data of a voltage and measurement data of a current from the data obtainment unit 111. The estimated voltage waveform calculation unit 115 receives the input of the value of each equivalent circuit parameter from the random number generation unit 114. Next, the estimated voltage waveform calculation unit 115 obtains a value obtained by performing Z-transform on the voltage measurement data. The estimated voltage waveform calculation unit 115 calculates an error value between the Z-transformed actual measurement value and the estimated value. The calculation of the error value will be described in detail below,

The estimated voltage is represented by the following equation (4). Ve(t) represents estimated voltage data. OCV is an open circuit voltage. Z0 represents an internal impedance. Im(t) represents current measurement data.

Ve(t)=OCV−ZOIm(t) (4)

Next, Laplace transform is performed on the equation (4), and the following equation (5) is obtained. Ve(s) is estimated voltage data on which Laplace transform is performed. Z0(s) is an internal impedance on which Laplace transform is performed. Im(s) is current measurement data on which Laplace transform is performed.

Ve(s)=OCV−ZO(s)Im(s) (5)

Next, Z-transform is performed on the equation (5), and the following equation (6) is obtained. Ve(z) is estimated voltage data on which Z-transform is performed. Z0(z) is an internal impedance on which Z-transform is performed. Im(z) is current measurement data on which Z-transform is performed.

Ve(z)=OCV−ZO(z)Im(z) (6)

Ez, which is an average square error between the estimated voltage data represented by the equation (6) and actual measurement voltage data, is represented by the equation (7). Vm(zi) is voltage measurement data of the i-th sample on which Z-transform is performed. Ve(zi) is estimated voltage data corresponding to the voltage measurement data of the i-th sample on which Z-transform is performed. Z0(zi) is an internal impedance corresponding to the voltage measurement data of the i-th sample on which Z-transform is performed. Im(zi) is current measurement data of the i-th sample on which Z-transform is performed N is the number of samples.

$$Ez = \sqrt{\frac{1}{N} {\sum }_{i = 1}^{N} {\{ Ve ( zi ) - Vm ( zi ) \}}^{2}} = \sqrt{\frac{1}{N} {\sum }_{i = 1}^{N} {\{ OCV - ZO ( zi ) Im ( zi ) - Vm ( zi ) \}}^{2}} \qquad ( 7 )$$

The estimated voltage waveform calculation unit 115 obtains Z0(zi) which is a Z-transformed internal impedance which minimizes Ez, which is a mean square error represented in the equation (7). Z0(z) which is a Z-transformed internal impedance is represented by the following equation (8).

$$Z 0 ( z ) = R 0 + {\sum }_{i = 1}^{2} \frac{RiT + {RiTz}^{- 1}}{T + 2 {C}_{i} {R}_{i} + ( T - 2 {C}_{i} {R}_{i} ) Z - 1} + Dw {\sum }_{i = 1}^{5} \frac{RwiT + {RwiTz}^{- 1}}{T + 2 CwiRwi + ( T - 2 CwiRwi ) {Z}^{- 1}} \qquad ( 8 )$$

The estimated voltage waveform calculation unit 115 calculates R0 to R2, C1, C2, and Dw, which are equivalent circuit parameters which minimize Ez, which is a mean square error illustrated in the equation (7), by using the equations (7) and (8). The estimated voltage waveform calculation unit 115 outputs the calculated minimum mean square error and the equivalent circuit parameter to the error comparison unit 116.

The error comparison unit 116 receives the input of the mean square error and the equivalent circuit parameter from the estimated voltage waveform calculation unit 115. In a case of the first estimation process, the mean square error is not yet stored in the storage unit 113. In the first estimation process, the error comparison unit 116 stores the mean square error obtained from the error comparison unit 116 in the storage unit 113. Thereafter, the error comparison unit 116 outputs an execution request for the estimation process to the initial value setting unit 112.

On the other hand, in a case of the second and subsequent estimation processes, the error comparison unit 116 compares a mean square error stored in the storage unit 113 with a mean square error obtained from the estimated voltage waveform calculation unit 115. In a case where the mean square error obtained from the estimated voltage waveform calculation unit 115 is smaller than the mean square error stored in the storage unit 113, the error comparison unit 116 updates the mean square error stored in the storage unit 113 into the mean square error obtained from the estimated voltage waveform calculation unit 115. The error comparison unit 116 updates an equivalent circuit parameter stored in the storage unit 113 by changing the equivalent circuit parameter to an equivalent circuit parameter obtained from the estimated voltage waveform calculation unit 115. Thereafter, the error comparison unit 116 outputs an execution request for the estimation process to the initial value setting unit 112.

On the other hand, in a case where the mean square error obtained from the estimated voltage waveform calculation unit 115 is equal to or greater than the mean square error stored in the storage unit 113, the error comparison unit 116 determines whether or not the number of repetitions of the equivalent circuit parameter convergence process from random number generation to error comparison is equal to or more than a convergence process count. In a case where the number of repetitions is less than the convergence process count, the error comparison unit 116 outputs an execution request of the random number generation process to the random number generation unit 114.

On the other hand, in a case where the number of repetitions is equal to or more than the convergence process count, the error comparison unit 116 determines whether or not the number of times an initial value is set is equal to or greater than an estimation process count. In a case where the number of initial value settings is less than the estimation process count, the error comparison unit 116 outputs an execution request for the estimation process to the initial value setting unit 112. On the other hand, in a case where the number of initial value settings is equal to or more than the estimation process count, the error comparison unit 116 determines the equivalent circuit parameter to be a value stored in the storage unit 113. Thereafter, the error comparison unit 116 outputs a completion notification of the analysis of the deterioration state to the deterioration diagnosis unit 101.

The estimated voltage waveform calculation unit 115 and the error comparison unit 116 correspond to examples of an “analysis unit”.

The deterioration diagnosis unit 101 receives the input of the completion notification of the analysis of the deterioration state from the error comparison unit 116. The deterioration diagnosis unit 101 obtains the equivalent circuit parameter from the storage unit 113. Thereafter, the deterioration diagnosis unit 101 obtains an index value by using the equivalent circuit parameter, and determines a deterioration state of the battery 3 by using the obtained index value.

For example, the deterioration diagnosis unit 101 obtains R0+R1+R2 as an index value. In a case where R0+R1+R2 exceeds a predetermined deterioration threshold value, the deterioration diagnosis unit 101 determines that the battery 3 is deteriorated. The deterioration threshold value is, for example, 2 times an index value of the battery 3 in an unused state.

Usually, in the equivalent circuit model 10, among the equivalent circuit parameters, R0 represents an electric field flow, and R1 and R2 represent electrodes. The deterioration diagnosis unit 101 may specify a deteriorated portion based on a type of the equivalent parameter determined to be deteriorated among R0 to R2.

When detecting the deterioration of the battery 3, the deterioration diagnosis unit 101 notifies the notification unit 102 of occurrence of the deterioration of the battery 3.

The notification unit 102 receives the notification of the occurrence of the deterioration of the battery 3 from the deterioration diagnosis unit 101. The notification unit 102 notifies the manager of the occurrence of the deterioration of the battery 3. For example, the notification unit 102 causes the display unit to display a message for notifying the occurrence of the deterioration of the battery 3, so the occurrence of the deterioration of the battery 3 is notified to the manager.

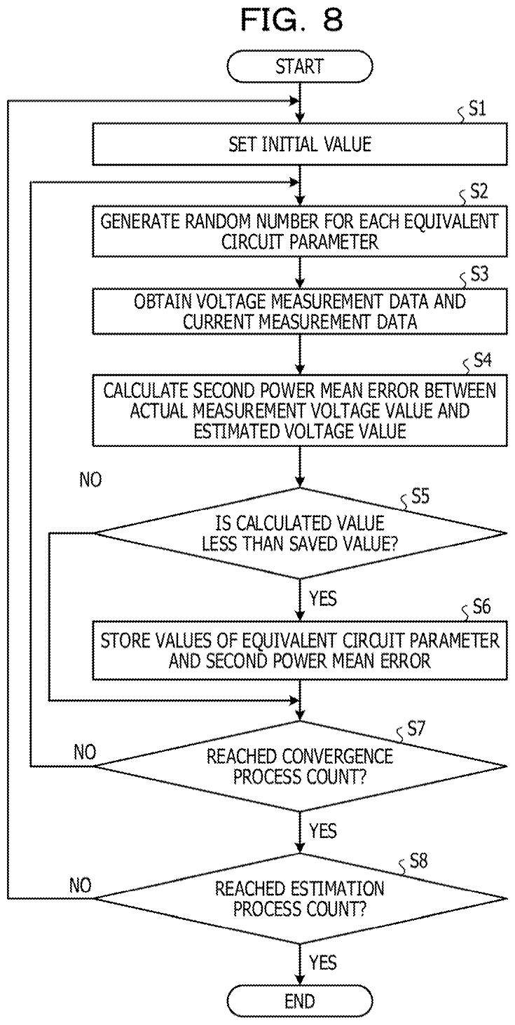

Next, a flow of the estimation process of the equivalent circuit parameter will be described with reference to FIG. 8. FIG. 8 is a flowchart of an estimation process of an equivalent circuit parameter.

The data obtainment unit 111 outputs voltage measurement data and current measurement data obtained from the data collection system 2 to the estimated voltage waveform calculation unit 115, and also instructs the initial value setting unit 112 to start an estimation process of equivalent circuit parameters. When the instruction for estimating the equivalent circuit parameter is received, the initial value setting unit 112 sets an initial value of each equivalent circuit parameter (step S1). The initial value setting unit 112 outputs the initial value of the equivalent circuit parameter to the random number generation unit 114.

The random number generation unit 114 receives the input of the initial value of each equivalent circuit parameter from the initial value setting unit 112. The random number generation unit 114 generates a random number by using the initial value for each equivalent circuit parameter (step S2). The random number generation unit 114 outputs the generated random number for each equivalent circuit parameter to the estimated voltage waveform calculation unit 115.

The estimated voltage waveform calculation unit 115 receives the input of the random number for each equivalent circuit parameter from the random number generation unit 114. The estimated voltage waveform calculation unit 115 obtains the voltage measurement data and the current measurement data from the data obtainment unit 111 (step S3).

Next, the estimated voltage waveform calculation unit 115 calculates a mean square error by using the equation (7) (step S4). The estimated voltage waveform calculation unit 115 obtains a value of the equivalent circuit parameter which minimizes a mean square error between an actual measurement voltage value and an estimated voltage value by using the equation (8). Thereafter, the estimated voltage waveform calculation unit 115 outputs the minimum value of the mean square error and the obtained value of the equivalent circuit parameter to the error comparison unit 116.

The error comparison unit 116 receives the input of the minimum value of the mean square error between the actual measurement voltage value and the estimated voltage value from the estimated voltage waveform calculation unit 115. Next, the error comparison unit 116 determines whether or not the calculated value of the mean square error by the estimated voltage waveform calculation unit 115 is less than a stored value of a mean square error stored in the storage unit 113 (step S5). In a case where the calculated value is equal to or greater than the stored value (NO in step S5), the error comparison unit 116 proceeds to step S7.

On the other hand, in a case where the calculated value is less than the stored value (YES in step S5), the error comparison unit 116 stores values of the equivalent circuit parameter and the mean square error in the storage unit 113, and updates the values thereof (step S6).

Next, the error comparison unit 116 determines whether or not the number of repetitions of a convergence process of the equivalent circuit parameter reaches a convergence process count (step S7). In a case where the number of repetitions does not reach the convergence process count (NO in step S7), the error comparison unit 116 requests the random number generation unit 114 to generate a random number, and the process returns to step S2.

On the other hand, in a case where the number of repetitions reaches the convergence process count (YES in step S7), the error comparison unit 116 determines whether or not the number of initial value settings reaches an estimation process count (step S8). In a case where the number of repetitions does not reach the estimation process count (NO in step S8), the error comparison unit 116 requests the initial value setting unit 112 to set the initial value, and the process returns to step S1.

On the other hand, in a case where the number of repetitions reaches the estimation process count (YES in step S8), the estimation process of the equivalent circuit parameter is completed, and a value stored in the storage unit 113 at that time is determined as a value of the equivalent circuit parameter of the equivalent circuit model 10 representing the battery 3.

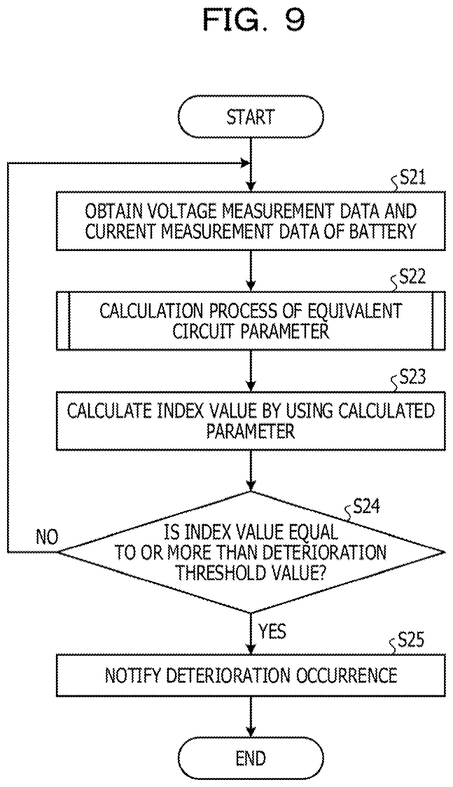

Next, an overall flow of a deterioration diagnosis process performed by the deterioration diagnosis server 1 will be described with reference to FIG. 9. FIG. 9 is a flowchart of the deterioration diagnosis process.

The deterioration state analysis unit 100 obtains voltage measurement data and current measurement data of the battery 3 from the data collection system 2 (step S21).

Next, the deterioration state analysis unit 100 executes a calculation process of an equivalent circuit parameter (step S22). The process illustrated in the flowchart in FIG. 8 is an example of the calculation process of the equivalent circuit parameter to be executed in step S22. Thereafter, the deterioration state analysis unit 100 notifies the deterioration diagnosis unit 101 of completion of analysis of a deterioration state.

The deterioration diagnosis unit 101 obtains the equivalent circuit parameter from the storage unit 113. Thereafter, the deterioration diagnosis unit 101 obtains an index value by using the equivalent circuit parameter (step S23).

The deterioration diagnosis unit 101 determines whether or not the index value is equal to or greater than a deterioration threshold value (step S24). A case where the deterioration threshold value represents an upper limit of the index value will be described. In a case where the index value is less than the deterioration threshold value (NO in step S24), the deterioration diagnosis unit 101 determines that the battery 3 is not deteriorated, and the deterioration diagnosis server 1 returns to step S21.

On the other hand, in a case where the index value is equal to or greater than the deterioration threshold value (YES in step S24), the deterioration diagnosis unit 101 notifies the notification unit 102 of detection of deterioration occurrence of the battery 3. In response to the notification from the deterioration diagnosis unit 101, the notification unit 102 notifies the manager of the occurrence of deterioration in the battery 3 (step S25).

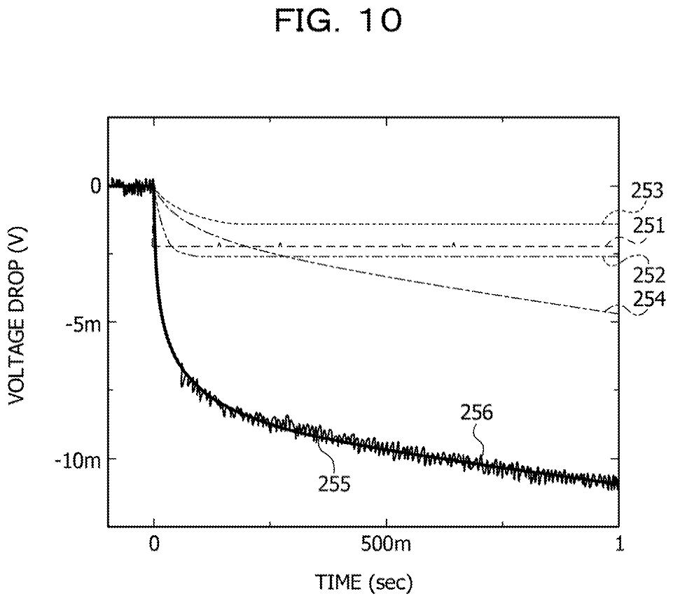

Next, an example of an analysis result of an internal impedance will be described with reference to FIG. 10. FIG. 10 is a diagram illustrating the example of the analysis result of the internal impedance. A line 256 in FIG. 10 is an actual measurement value of an open voltage of a certain battery 3. On the other hand, the deterioration diagnosis server 1 calculates equivalent circuit parameters of the battery 3 as R0=4.6 mΩ, R1=5.4 mΩ, R2=2.7 mΩ, C1=3.9 F, C2=19 F, and Dw=8.3 m. In this case, a mean square error of the voltage measurement data and the estimated voltage data is 0.125 mV.

In FIG. 10, a line 251 represents a voltage drop caused by the resistor 12 in the equivalent circuit model 10. A line 252 represents a voltage drop caused by the CR circuit including the resistor 13 and the capacitor 14. A line 253 represents a voltage drop caused by the CR circuit including the resistor 15 and the capacitor 16. The line 253 also represents a voltage drop caused by the Warburg impedance 17. The lines 251 to 253 are obtained by using the equivalent circuit parameter calculated by the deterioration diagnosis server 1.

A sum of respective components of the lines 251 to 254 is a line 255. The line 255 is approximate to the line 256 which is actual measurement data, and it may be seen that the deterioration state analysis unit 100 accurately generates a transient response waveform.

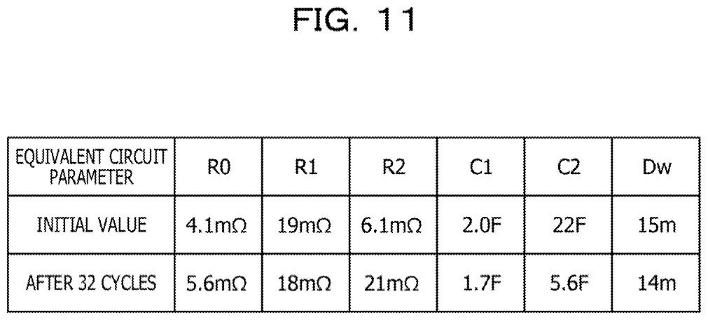

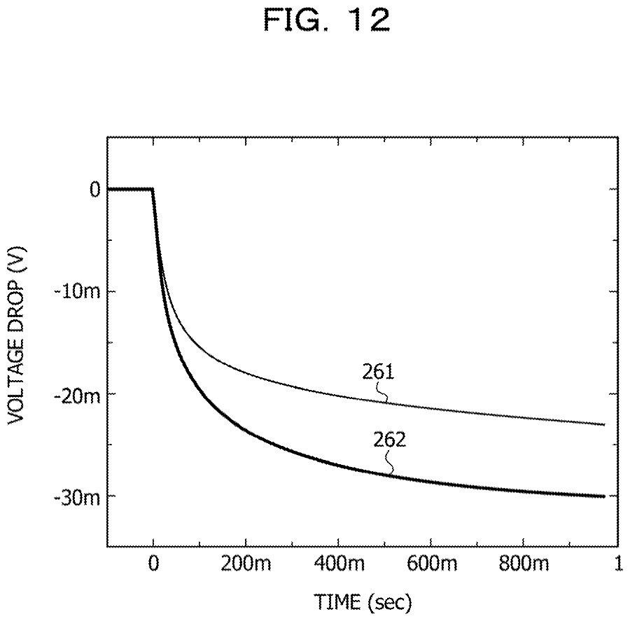

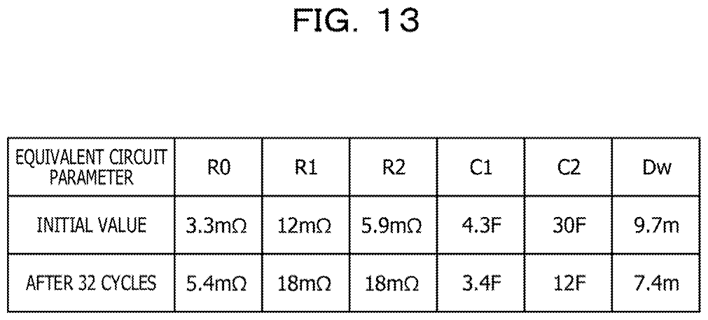

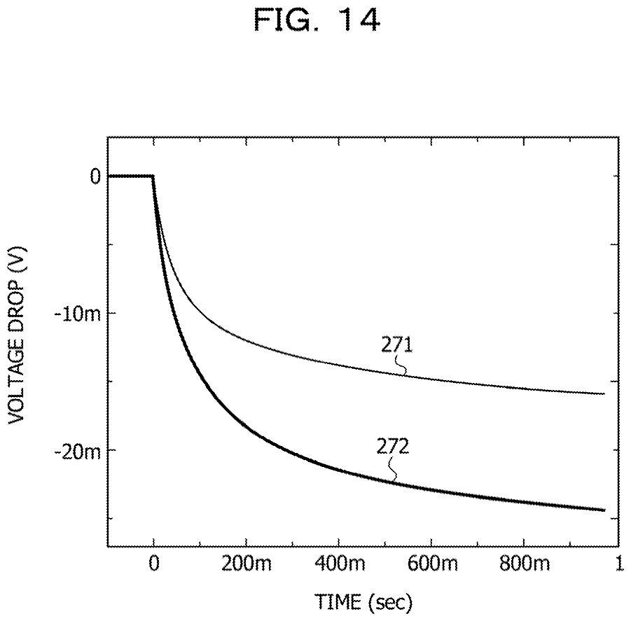

Next, accuracy of the deterioration diagnosis will be described with reference to FIGS. 11 to 14. FIG. 11 is a diagram illustrating an estimated value of an equivalent circuit parameter in a case where a battery of 4.5 Ah is used. FIG. 12 is a diagram illustrating an actual measurement value in a case where a battery of 4.5 Ab is used, FIG. 13 is a diagram illustrating an estimated value of an equivalent circuit parameter in a case where a battery of 8.0 Ah is used. FIG. 14 is a diagram illustrating an actual measurement value in a case where a battery of 8.0 Ah is used.

As illustrated in FIG, 11, in an initial state before use of a certain battery 3 of 4.5 Ah, the deterioration diagnosis server 1 calculates equivalent circuit parameters as R0=4.1 mΩ, R1=19 mΩ, R2=6.1 mΩ, C1=2.0 F, C2=22 F, and Dw=15 m. After 32 cycles for the same battery 3 having 4.5 Ah, the deterioration diagnosis server 1 calculates equivalent circuit parameters as R0=5.6 mΩ, R1=18 mΩ, R2=21 mΩ, C1=1.7 F, C2=5.6 F, and Dw=14 m. In this case, since R2 changes greatly from 6.1 mΩ to 21 mΩ, deterioration diagnosis server 1 may detect occurrence of deterioration in the battery 3.

On the other hand, with reference to FIG. 12, a transient waveform illustrated by a line 261, for example, is obtained from actual measurement data in an initial state before use of the same battery 3 having 4.5 Ah. A transient response waveform indicated by a line 262 is obtained from actual measurement data after 32 cycles of the same battery 3 having 4.5 Ah. In this manner, it may be confirmed that the battery 3 is also deteriorated over the actual measurement data, and the deterioration diagnosis by the deterioration diagnosis server 1 is accurate.

As illustrated in FIG. 13, in an initial state before use of a certain battery 3 of 8.0 Ah, the deterioration diagnosis server 1 calculates equivalent circuit parameters as R0=3.3 mΩ, R1=12 mΩ, R2=5.9 mΩ, C1=4.3 F, C2=30 F, and Dw=9.7 m. After 32 cycles for the same battery 3 having 8.0 Ah, the deterioration diagnosis server 1 calculates equivalent circuit parameters as R0=5.4 mΩ, R1=18 mΩ, R2=18 mΩ, C1=3.4 F, C2=12 F, and Dw=7.4 m. In this case, since R2 changes greatly from 5.9 mΩ to 18 mΩ, the deterioration diagnosis server 1 may detect occurrence of deterioration in the battery 3.

On the other hand, with reference to FIG. 14, a transient response waveform illustrated by a line 271, for example, is obtained from actual measurement data in the initial state before use of the same battery 3 having 8.0 Ah. A transient response waveform indicated by a line 272 is obtained from actual measurement data after 32 cycles of the same battery 3 having 8.0 Ah. In this manner, it may be confirmed that the battery 3 is also deteriorated over the actual measurement data, and the deterioration diagnosis by the deterioration diagnosis server 1 is accurate.

### (Hardware Configuration)

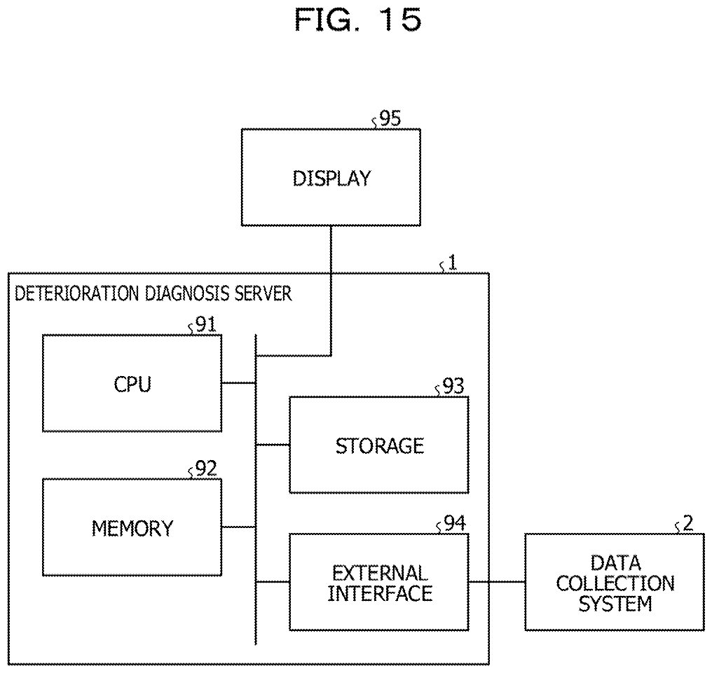

Next, a hardware configuration of the deterioration diagnosis server 1 will be described with reference to FIG. 15, FIG. 15 is a hardware configuration diagram of a deterioration diagnosis server.

The deterioration diagnosis server 1 includes a central processing unit (CPU) 91, a memory 92, a storage 93, and an external interface 94. A display 95 is coupled to the deterioration diagnosis server 1.

The external interface 94 is coupled to the data collection system 2. The external interface 94 transmits data obtained from the data collection system 2 to the CPU 91 via a bus.

The CPU 91 is coupled to the memory 92, the storage 93, the external interface 94, and the display 95 via the bus. The CPU 91 transmits and receives data to and from the memory 92, the storage 93, the external interface 94, and the display 95 via the bus.

The storage 93 is a storage device such as a hard disk, a solid state drive (SSD), or the likes The storage 93 realizes a function of the storage unit 113 illustrated in FIG. 7, for example. The storage 93 stores various programs including programs for realizing functions of the data obtainment unit 111, the initial value setting unit 112, the random number generation unit 114, the estimated voltage waveform calculation unit 115, the error comparison unit 116, the deterioration diagnosis unit 101, and the notification unit 102 illustrated in FIG. 7.

The CPU 91 reads various programs from the storage 93, expands the programs onto the memory 92, and executes the programs. Accordingly, the CPU 91 and the memory 92 realize functions of the data obtainment unit 111, the initial value setting unit 112, the random number generation unit 114, the estimated voltage waveform calculation unit 115, the error comparison unit 116, the deterioration diagnosis unit 101, and the notification unit 102 illustrated in FIG. 7.

In this embodiment, the case where the deterioration diagnosis server 1 includes the deterioration state analysis unit 100, the deterioration diagnosis unit 101, and the notification unit 102 is described, but the embodiment may have another configuration. For example, a device having a function of the deterioration state analysis unit 100 may be disposed, and a device having the functions of the deterioration diagnosis unit 101 and the notification unit 102 may perform deterioration diagnosis based on an equivalent circuit parameter output from the device.

As described above, the deterioration diagnosis server according to the present embodiment estimates a transient response waveform based on an equivalent circuit model of a battery represented by using an approximate solution of a Warburg impedance obtained by using an equivalent circuit including CR circuits of 5 stages. The deterioration diagnosis server performs deterioration diagnosis on the battery by using equivalent circuit parameters corresponding to the estimated transient response waveform.

By calculating an approximate solution of a Warburg impedance using the equivalent circuit including the CR circuits of 5 stages, it is possible to analyze a frequency of 3 digits with a filter having a resonance frequency of 5 digits. In a case where a time constant of the CR circuit of several 10 of msec is analyzed, a range of a sampling frequency is 1 kHz. According to a sampling theorem, the frequency of 1 kHz does not include information equal to or more than 500 Hz. For analysis for one second, it is desirable to perform the analysis up to a frequency of 0.5 Hz in a frequency range. For example, in a case where a time constant of the CR circuit of several 10 of msec is analyzed, it is preferable to analyze a frequency of 3 digits.

In this respect, in a case where a normal foster type equivalent circuit is used, a step of a time constant of CR circuits is performed at (2n−1)². For example, in order to analyze the frequency of 3 digits by using the normal foster type equivalent circuit, 16 CR circuits are used. On the other hand, in the equivalent circuit according to the present embodiment, a step of a time constant of CR circuits is performed at 10ⁿ. For example, in order to analyze the frequency of 3 digits by using the equivalent circuit according to the present embodiment, at least three CR circuits may be used. In the diagnosis server according to the present embodiment, the equivalent circuit using the 5 CR circuits is used to accurately analyze the frequency of 3 digits.

As described above, in the equivalent circuit model used by the deterioration diagnosis server according to the present embodiment, it is possible to analyze the frequency of 3 digits by approximating the Warburg impedance with the equivalent circuit including the CR circuits of 5 stages, and it is possible to calculate the Warburg impedance with a small amount of calculation. For example, in the equivalent circuit model used by the deterioration diagnosis server according to the present embodiment, the Warburg impedance is obtained in a calculation time of one-third of that in a case where a normal foster type equivalent circuit is used.

The deterioration diagnosis server according to the present embodiment performs deterioration diagnosis on the battery by using an equivalent circuit model using a Warburg impedance with high accuracy, so it possible to perform deterioration diagnosis with high accuracy. For example, the deterioration diagnosis server according to the present embodiment may accurately perform life diagnosis on a storage battery with a small amount of calculation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing apparatus comprising:
a memory; and
a processor coupled to the memory and configured to:
obtain an actual measurement voltage at a time of a voltage change of a battery;
estimate an internal impedance of the battery based on an equivalent circuit model of the battery in which a Warburg impedance is represented by an approximate equation using an equivalent circuit which is a series circuit of CR circuits and has steps of a power of 10 as a time constant of the CR circuit and the actual measurement voltage;
determine a deterioration state of the battery based on the internal impedance; and
notify of deterioration of the battery in a case where the deterioration diagnosis unit detects deterioration.

2. The information processing apparatus according to claim 1
wherein the equivalent circuit includes the five CR circuits.

3. The information processing apparatus according to claim 1
wherein the approximate equation is an equation which approximates a calculation result obtained by Z-transform on a Warburg impedance.

4. The information processing apparatus according to claim 1,
wherein the processor is configured to:
obtain an actual measurement current;
calculate an equivalent circuit parameter included in the equivalent circuit model in which an error between an estimated voltage calculated based on the equivalent circuit model and the actual measurement current and the actual measurement voltage is minimized; and
determine a deterioration state of the battery based on the equivalent circuit parameter.

5. An information processing apparatus comprising:
a memory; and
a processor coupled to the memory and configured to:
obtain an actual measurement voltage at a time of a voltage change of a battery; and
estimate an internal impedance of the battery based on an equivalent circuit model of the battery in which a Warburg impedance is represented by an approximate equation using an equivalent circuit which is a series circuit of CR circuits and has steps of a power of 10 as a time constant of the CR circuit and the actual measurement voltage.

6. A non-transitory computer-readable recording medium storing a battery deterioration diagnosis program causing a computer to execute a process, the process comprising:
obtaining an actual measurement voltage at a time of a voltage change of a battery;
estimating an internal impedance of the battery based on an equivalent circuit model of the battery in which a Warburg impedance is represented by an approximate equation using an equivalent circuit which is a series circuit of CR circuits and has steps of a power of 10 as a time constant of the CR circuit and the obtained actual measurement voltage;
determining a deterioration state of the battery based on the estimated internal impedance; and
notifying of deterioration of the battery in a case where the deterioration is detected.

7. The non-transitory computer-readable recording medium according to claim 6,
wherein the equivalent circuit includes the five CR circuits.

8. The non-transitory computer-readable recording medium according to claim 6,
wherein the approximate equation is an equation which approximates a calculation result obtained by Z-transform on a Warburg impedance.

9. The non-transitory computer-readable recording medium according to claim 6, further comprising:
obtaining an actual measurement current,
calculating an equivalent circuit parameter included in the equivalent circuit model in which an error between an estimated voltage calculated based on the equivalent circuit model and the actual measurement current and the actual measurement voltage is minimized; and
determining a deterioration state of the battery based on the equivalent circuit parameter.
